(19) United States
(12) Patent Application Publication
(10) Pub. No.: US 2022/0399477 A1
(43) Pub. Date: Dec. 15, 2022

(54) MICRO LIGHT-EMITTING DIODE DEVICE STRUCTURE

(71) Applicant: MIKRO MESA TECHNOLOGY CO., LTD., Apia (WS)

(72) Inventor: Li-Yi CHEN, Tainan City (TW)

(21) Appl. No.: 17/342,562

(22) Filed: Jun. 9, 2021

(51) Int. Cl. H01L 33/38; H01L 33/42; H01L 33/44

(52) U.S. Cl. CPC H01L 33/38; H01L 33/42; H01L 33/44

(57) ABSTRACT

A micro light-emitting diode device structure including a substrate, a micro light-emitting diode, an isolation layer, and a top electrode is provided. A height of a contact periphery between the micro light-emitting diode and a concave surface of the isolation layer is greater than a height of a flat surface of the isolation layer and is smaller than a height of the micro light-emitting diode. A height of the isolation layer decreases from the height of the contact periphery to the height of the flat surface in a direction away from the micro light-emitting diode. In a cross-section, an included angle between the flat surface and a virtual straight line connecting the contact periphery and a turning periphery is greater than 120 degrees. The turning periphery is a boundary between the concave surface and the flat surface.

### BACKGROUND

### Field of Invention

The present disclosure relates to a micro light-emitting diode device structure.

### Description of Related Art

The statements in this section merely provide background information related to the present disclosure and do not necessarily constitute prior art.

As a light source, light-emitting diodes (LEDs) have many advantages, including low energy consumption, long lifetime, small size, and fast switching. Hence, conventional lighting, such as incandescent lighting, is gradually replaced by LED lights. The properties regarding LEDs also fit applications on displays. Researches on displays using micro light-emitting devices, or specifically, micro light-emitting diodes (μ-LEDs), have become popular in recent years. Commercial lighting applications made of μ-LEDs are nearly within reach.

As the pixel size of the μ-LEDs display shrinks, it is necessary to review many details on manufacturing processes. Among them, preventing electrodes from cracking during manufacturing in a compact structure and avoiding a short circuit between a p-type semiconductor layer and an n-type semiconductor layer of the μ-LED are important issues.

### SUMMARY

According to some embodiments of the present disclosure, a micro light-emitting diode device structure is provided. The micro light-emitting diode device structure includes a substrate, a micro light-emitting diode on the substrate, an isolation layer, and a top electrode. The micro light-emitting diode includes a first type semiconductor layer, a second type semiconductor layer, and an active layer. The second type semiconductor layer is on the first type semiconductor layer. The active layer is between the first type semiconductor layer and the second type semiconductor layer. A top surface of the second type semiconductor layer has a first height with respect to a front surface of the substrate. A ratio of a lateral length of the micro light-emitting diode to the first height is smaller than 20, and the lateral length is smaller than 50 μm.

The isolation layer is on the substrate and surrounds the micro light-emitting diode. The isolation layer has a flat portion and a concave portion between the flat portion and the micro light-emitting diode. The flat portion has a flat surface facing away from the substrate. The concave portion has a concave surface facing away from the substrate. The concave portion is in contact with a side surface of the micro light-emitting diode. The second type semiconductor layer is exposed from the isolation layer. The top electrode covers and is in contact with the second type semiconductor layer and the isolation layer.

A contact periphery between the micro light-emitting diode and the concave surface has a second height with respect to the front surface. The flat surface has a third height with respect to the front surface. The second height is greater than the third height and smaller than the first height. A height of the isolation layer with respect to the front surface decreases from the second height to the third height in a direction away from the side surface.

In a cross-section of the micro light-emitting diode device structure perpendicular to the front surface, an included angle between the flat surface and a virtual straight line connecting the contact periphery and a turning periphery is greater than 120 degrees. The turning periphery is a boundary of the concave surface and the flat surface.

According to some embodiments of the present disclosure, a micro light-emitting diode device structure is provided. The micro light-emitting diode device structure includes a substrate, a micro light-emitting diode on the substrate, an isolation layer, and a top electrode. The micro light-emitting diode includes a first type semiconductor layer, a second type semiconductor layer, and an active layer. The second type semiconductor layer is on the first type semiconductor layer. The active layer is between the first type semiconductor layer and the second type semiconductor layer. A top surface of the second type semiconductor layer has a first height with respect to a front surface of the substrate. A ratio of a lateral length of the micro light-emitting diode to the first height is smaller than 20, and the lateral length is smaller than 50 μm.

The isolation layer is on the substrate and surrounds the micro light-emitting diode. The isolation layer has a concave surface facing away from the substrate. The isolation layer is in contact with a side surface of the micro light-emitting diode. The second type semiconductor layer is exposed from the isolation layer. The top electrode covers and is in contact with the second type semiconductor layer and the isolation layer.

A contact periphery between the micro light-emitting diode and the concave surface has a second height with respect to the front surface. The second height is smaller than the first height. A height of the isolation layer with respect to the front surface decreases from the second height to zero in a direction away from the side surface. In a cross-section of the micro light-emitting diode device structure perpendicular to the front surface, an included angle between the front surface and a virtual straight line connecting the contact periphery and a turning periphery is greater than 120 degrees. The turning periphery is a boundary of the concave surface and the front surface.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a schematic cross-sectional view of a micro light-emitting diode device structure according to some embodiments of the present disclosure;

FIG. 2 is a schematic cross-sectional view near a side surface of a micro light-emitting diode in contact with an isolation layer according to some embodiments of the present disclosure;

FIG. 3A is a schematic top view of a micro light-emitting diode device structure according to some embodiments of the present disclosure;

FIG. 3B is a schematic top view of a micro light-emitting diode device structure according to some embodiments of the present disclosure;

FIG. 4A is a schematic cross-sectional view of a micro light-emitting diode device structure according to some embodiments of the present disclosure;

FIG. 4B is a schematic cross-sectional view of a micro light-emitting diode device structure according to some embodiments of the present disclosure;

FIG. 5A is a schematic cross-sectional view of a micro light-emitting diode device structure according to some embodiments of the present disclosure; and

FIG. 5B is a schematic cross-sectional view of a micro light-emitting diode device structure according to some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

In various embodiments, description is made with reference to figures. However, certain embodiments may be practiced without one or more of these specific details, or in combination with other known methods and configurations. In the following description, numerous specific details are set forth, such as specific configurations, dimensions, and processes, etc., in order to provide a thorough understanding of the present disclosure. In other instances, well-known semiconductor processes and manufacturing techniques have not been described in particular detail in order to not unnecessarily obscure the present disclosure. Reference throughout this specification to “one embodiment,” “an embodiment”, “some embodiments” or the like means that a particular feature, structure, configuration, or characteristic described in connection with the embodiment is included in at least one embodiment of the disclosure. Thus, the appearances of the phrase “in one embodiment,” “in an embodiment”, “according to some embodiments” or the like in various places throughout this specification are not necessarily referring to the same embodiment of the disclosure. Furthermore, the particular features, structures, configurations, or characteristics may be combined in any suitable manner in one or more embodiments.

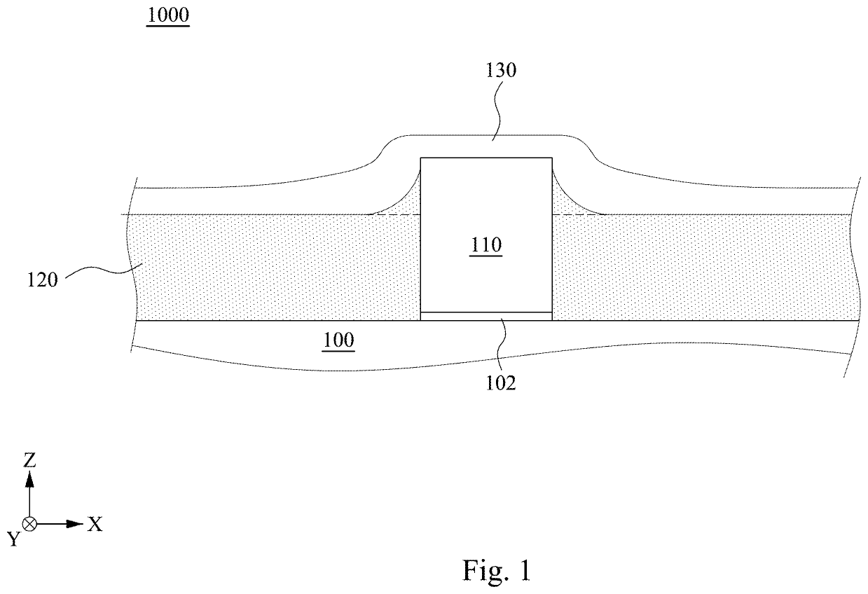

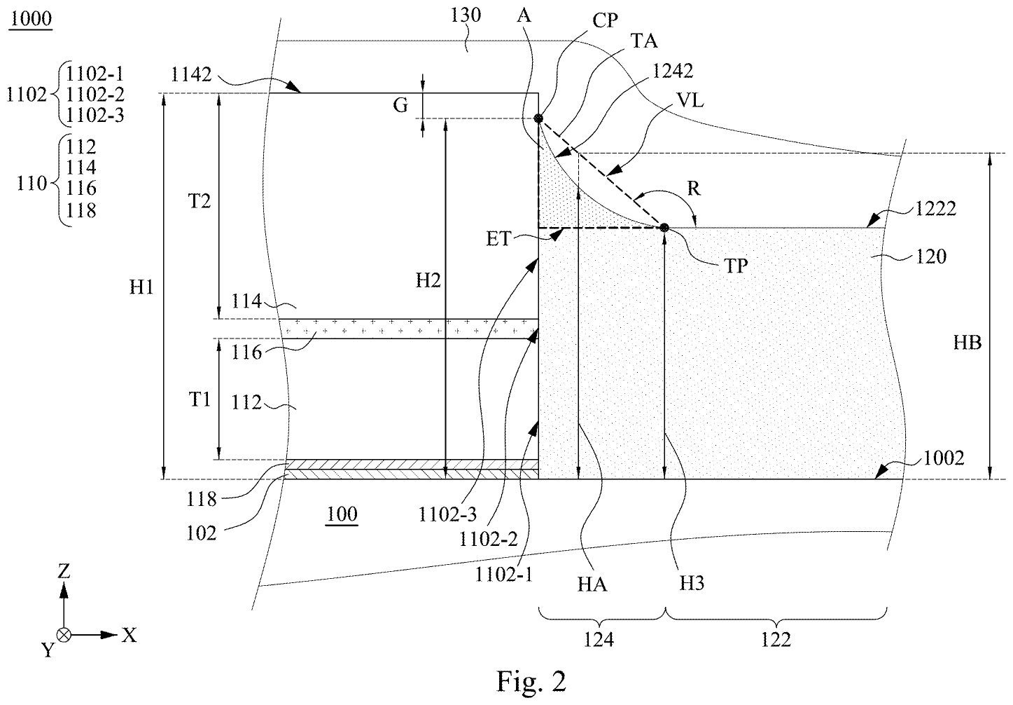

Reference is made to FIGS. 1 and 2. FIG. 1 is a schematic cross-sectional view of a micro light-emitting diode device structure 1000 according to some embodiments of the present disclosure. FIG. 2 is a schematic cross-sectional view near a side surface 1102 of a micro light-emitting diode 110 in contact with an isolation layer 120 according to some embodiments of the present disclosure. In some embodiments, the micro light-emitting diode device structure 1000 includes a substrate 100, a micro light-emitting diode 110 on the substrate 100, an isolation layer 120, and a top electrode 130. The micro light-emitting diode 110 includes a first type semiconductor layer 112, a second type semiconductor layer 114 on the first type semiconductor layer 112, and an active layer 116 between the first type semiconductor layer 112 and the second type semiconductor layer 114. In some embodiments, the substrate 100 includes a conductive layer 102 thereon. The micro light-emitting diode 110 further includes a bonding electrode 118 on the first type semiconductor layer 112. The conductive layer 102 is in contact with the bonding electrode 118.

In some embodiments, the first type semiconductor layer 112 is a p-type semiconductor layer, and the second type semiconductor layer 114 is an n-type semiconductor layer. In some embodiments, a thickness T2 of the second type semiconductor layer 114 is greater than a thickness T1 of the first type semiconductor layer 112, so that the tolerance of an error of a height HA of the isolation layer 120 during fabrication is better, and also the current can spread more uniformly in the micro light-emitting diode 110. The uniformity of the current, as mentioned, is due to the better conductivity of the n-type semiconductor than that of the p-type semiconductor.

A top surface 1142 of the second type semiconductor layer 114 has a first height H1 with respect to a front surface 1002 of the substrate 100. A lateral length L of the micro light-emitting diode 110 is smaller than 50 μm. A ratio of the lateral length L of the micro light-emitting diode 110 to the first height H1 is smaller than 20. Specifically, as said ratio becomes greater, more light is totally reflected at a top surface 1142 of the micro light-emitting diode 110, which decreases the light extraction efficiency. With the limitation of said ratio, a total reflection of the light emitted from the active layer 116 can be significantly reduced.

The isolation layer 120 is on the substrate 100 and surrounds the micro light-emitting diode 110. The isolation layer 120 can be made of positive photoresist, negative photoresist, or resin. In some embodiments, the isolation layer 120 has a flat portion 122 and a concave portion 124. The concave portion 124 is between the flat portion 122 and the micro light-emitting diode 110. The flat portion 122 has a flat surface 1222 facing away from the substrate 100. The concave portion 124 has a concave surface 1242 facing away from the substrate 100. The concave portion 124 is in contact with the side surface 1102 of the micro light-emitting diode 110. The second type semiconductor layer 114 is exposed from the isolation layer 120. The top electrode 130 is in contact with and covers the second type semiconductor layer 114 and the isolation layer 120. In some embodiments, the first type semiconductor layer 112 and the second type semiconductor layer 114 are in contact with the isolation layer 120. In some embodiments, a side surface 1102-1 of the first type semiconductor layer 112 and a side surface 1102-2 of the active layer 116 are entirely covered by and in contact with the isolation layer 120, so as to prevent a short circuit between the first type semiconductor layer 112 and the second type semiconductor layer 114. A side surface 1102-3 of the second type semiconductor layer 114 is partially covered by and in contact with the isolation layer 120.

A contact periphery CP between the micro light-emitting diode 110 and the concave surface 1242 has a second height H2 with respect to the front surface 1002. In a cross-section of the micro light-emitting diode device structure 1000 perpendicular to the front surface 1002 as shown in FIG. 2, the contact periphery CP is the highest point of the isolation layer 120. The flat surface 1222 has a third height H3 with respect to the front surface 1002. The second height H2 is greater than the third height H3 and smaller than the first height H1. In some embodiments, a difference between the first height H1 and the second height H2 is greater than 0 μm and smaller than 3.5 μm. If the difference is too large, a gap G between the top surface 1142 and the isolation layer 120 (i.e., the contact periphery CP) is too large and will cause cracks on the top electrode 130 which covers the top surface 1142 and the isolation layer 120. Furthermore, if the difference is greater than 3.5 μm, the contact periphery CP will be too close to the active layer 116 and the probability of a short circuit between the first type semiconductor layer 112 and the second type semiconductor layer 114 may significantly increase. The height HA of the isolation layer 120 with respect to the front surface 1002 decreases from the second height H2 to the third height H3 in a direction away from the side surface 1102. In FIG. 2, the direction is the X direction.

In the cross-section as shown in FIG. 2, an included angle R between the flat surface 1222 and a virtual straight line VL connecting the contact periphery CP and a turning periphery TP is greater than 120 degrees and smaller than 180 degrees. The turning periphery TP is a boundary between the concave surface 1242 and the flat surface 1222. In other words, after passing through the turning periphery TP in the X direction (the direction away from the side surface 1102), the height HA of the isolation layer 120 becomes a constant. If the included angle R is too small, a variation of a height from the top surface 1142 to the flat surface 1222 will be too steep, and the quality of the top electrode 130 will be reduced significantly. In the embodiments of the present disclosure, the above features can be formed by mask-free methods, such as spin coating the isolation layer 120 around the micro light-emitting diode 110 together with pre-adjustment of a viscosity coefficient of the isolation layer 120.

In some embodiments, the concave surface 1242 is between an extension ET of the flat surface 1222 and the virtual straight line VL in the cross-section as shown in FIG. 2. The extension ET is extended in the direction towards the side surface 1102 (i.e., the −X direction as shown in FIG. 2). That is, the height HA of the isolation layer 120 with respect to the front surface 1002 is always smaller than a height HB of the virtual straight line VL with respect to the front surface 1002. The comparison as mentioned between the heights HA and HB is under the premise of the same distance with respect to the side surface 1102, as schematically denoted in FIG. 2. With the above conditions related to the included angle R and the concave surface 1242, the micro light-emitting diode device structure 1000 can prevent particles or ions from penetrating through the isolation layer 120 and reaching the active layer 116 or the first type semiconductor layer 112 during various fabrication processes. At the same time, the quality of the top electrode 130 is maintained.

In some embodiments, the virtual straight line VL, the side surface 1102, and the extension ET of the flat surface 1222 form a triangular area TA in the cross-section as shown in FIG. 2. To further enhance the benefit illustrated in the previous paragraph, a filling rate of an area A of the isolation layer 120 within the triangular area TA with respect to the triangular area TA is manufactured to be greater than 30% and smaller than 100% in said cross-section. The limitation of the filling rate ensures the concave feature of the concave surface 1242 and a smooth variation of the height HA of the isolation layer 120 are met simultaneously.

In some embodiments, a refractive index of the isolation layer 120 is smaller than a refractive index of the top electrode 130. In some embodiments, the refractive index of the top electrode 130 is smaller than refractive indices of the first type semiconductor layer 112 and the second type semiconductor layer 114. In some embodiments, a transmittance of the top electrode 130 is greater than 60%. Under the above conditions, the light emitted from the active layer 116 is more likely to propagate out of the micro light-emitting diode device structure 1000 upwards (i.e., in the Z direction).

In some embodiments, the top electrode 130 includes metal nanowires, such as silver nanowires. When the top electrode 130 includes metal nanowires, cracks can be prevented due to the flexibility of the conductive nanowires. In addition, metal nanowires have low resistivity compared to transparent materials such as indium tin oxide (ITO). Therefore, the top electrode 130 with the conductive nanowires can be fabricated to form a thin conductive film to increase transparency. At the same time, the resistivity remains the same as compared to the thicker electrode without the conductive nanowires.

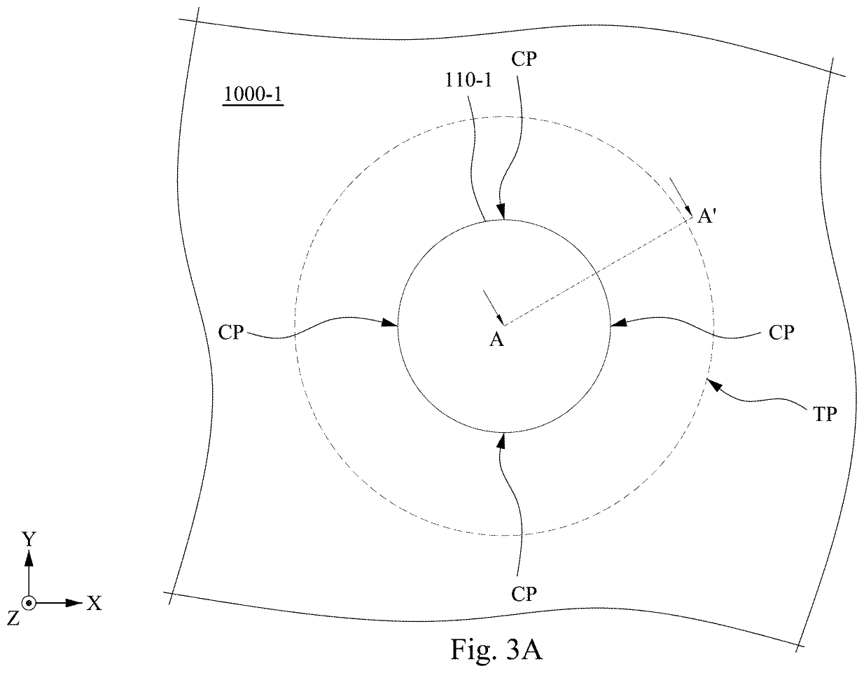

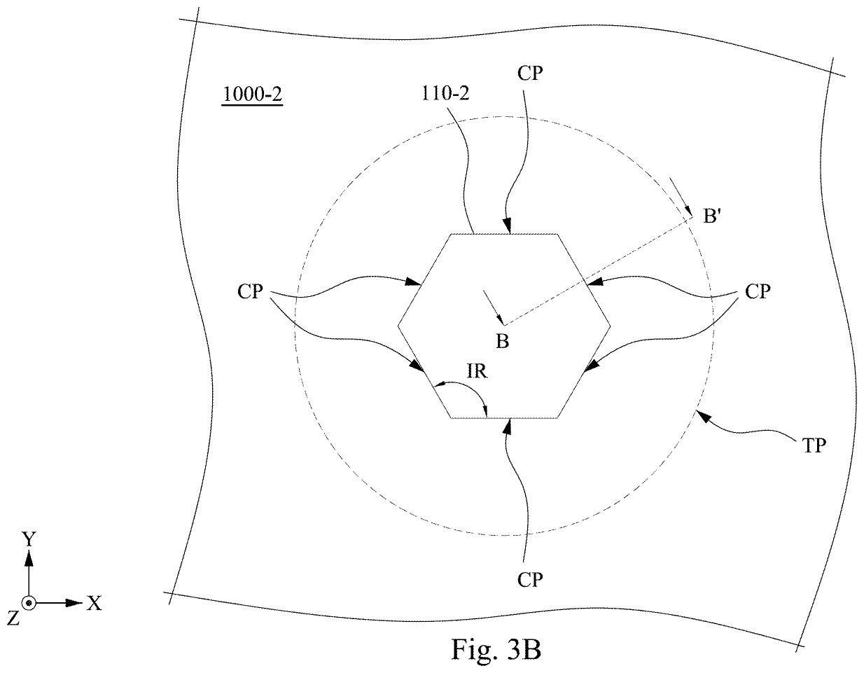

Reference is made to FIGS. 3A and 3B. FIG. 3A is a schematic top view of a micro light-emitting diode device structure 1000-1 according to some embodiments of the present disclosure. FIG. 3B is a schematic top view of a micro light-emitting diode device structure 1000-2 according to some embodiments of the present disclosure. FIGS. 3A and 3B illustrate two types of the micro light-emitting diode device structure 1000 as shown in FIGS. 1 and 2. In some embodiments, a vertical projection of the contact periphery CP on the front surface 1002 is in the shape of a circle, as shown in FIG. 3A. In some embodiments, a vertical projection of the contact periphery CP on the front surface 1002 is in the shape of a polygon, and each of interior angles IR of the polygon is greater than 90 degrees, as shown in FIG. 3B. The condition of greater than 90 degrees ensures a lower probability of total reflection of the light emitted from the active layer 116 on the contact periphery CP (i.e., on the edge of the micro light-emitting diode device structure 1000-2) in the top view. It is noted that the shape of a circle of the contact periphery CP may have the lowest probability of said total reflection. It is noted that the cross-sectional view in FIG. 2 can be derived from a line A-A′ of FIG. 3A or a line B-B′ of FIG. 3B, and should not be limited thereto. In some embodiments, extensions of the line A-A′ and the line B-B′ respectively pass through geometrical centers of a micro light-emitting diode 110-1 (i.e., a circle) and a micro light-emitting diode 110-2 (i.e., a hexagon) in the top view.

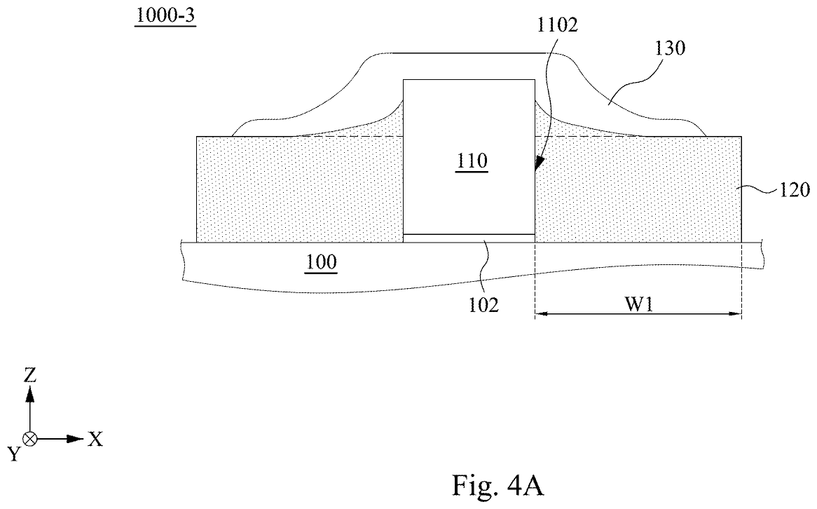

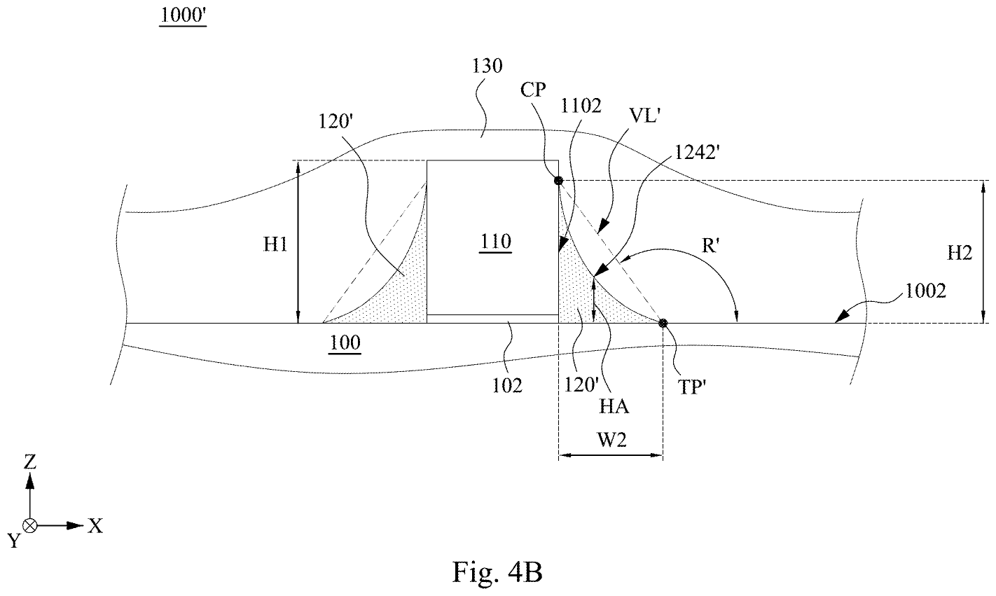

Reference is made to FIGS. 4A and 4B. FIG. 4A is a schematic cross-sectional view of a micro light-emitting diode device structure 1000-3 according to some embodiments of the present disclosure. FIG. 4B is a schematic cross-sectional view of a micro light-emitting diode device structure 1000′ according to some embodiments of the present disclosure. In some embodiments, a width W1 (see FIG. 4A) and a width W2 (see FIG. 4B) of the isolation layer 120 with respect to the side surface 1102 is greater than 1 μm. It is noted that the isolation layers 120 and 120′ in the embodiments of the present disclosure can be fabricated by mask-free methods, such as spin coating. If the width W1 and W2 is smaller than 1 μm, it can only be completed with the help of a photomask, which means at least one more step is needed in the whole manufacturing processes. In other words, the limitation of the width W1 and W2 implies that simpler and effective manufacturing processes are possible. In FIGS. 4A and 4B, the widths W1 and W2 are measured from the side surface 1102 in the X direction until a position without the existence of the isolation layers 120 and 120′.

Differences between the embodiments illustrated by FIG. 4B and the embodiments illustrated by FIGS. 2 and 4A are pointed out as follows. In FIG. 4B, the height HA of the isolation layer 120′ with respect to the front surface 1002 decreases from the second height H2 to zero in a direction away from the side surface 1102. In the cross-section of the micro light-emitting diode device structure 1000′ perpendicular to the front surface 1002 as shown in FIG. 4B, an included angle R′ between the front surface 1002 and a virtual straight line VL′ connecting the contact periphery CP and a turning periphery TP′ is greater than 120 degrees. The turning periphery TP′ is a boundary between a concave surface 1242′ and the front surface 1002.

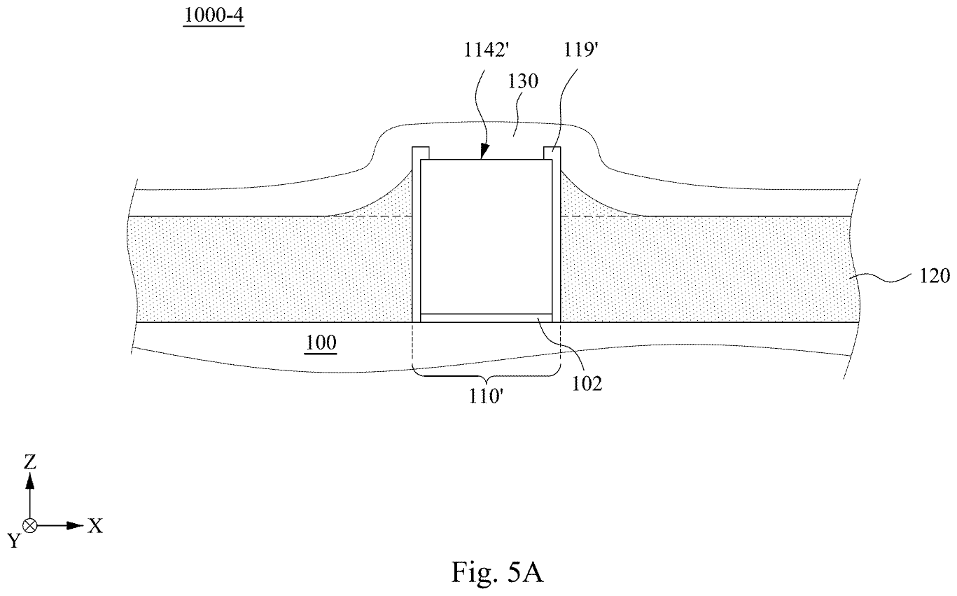

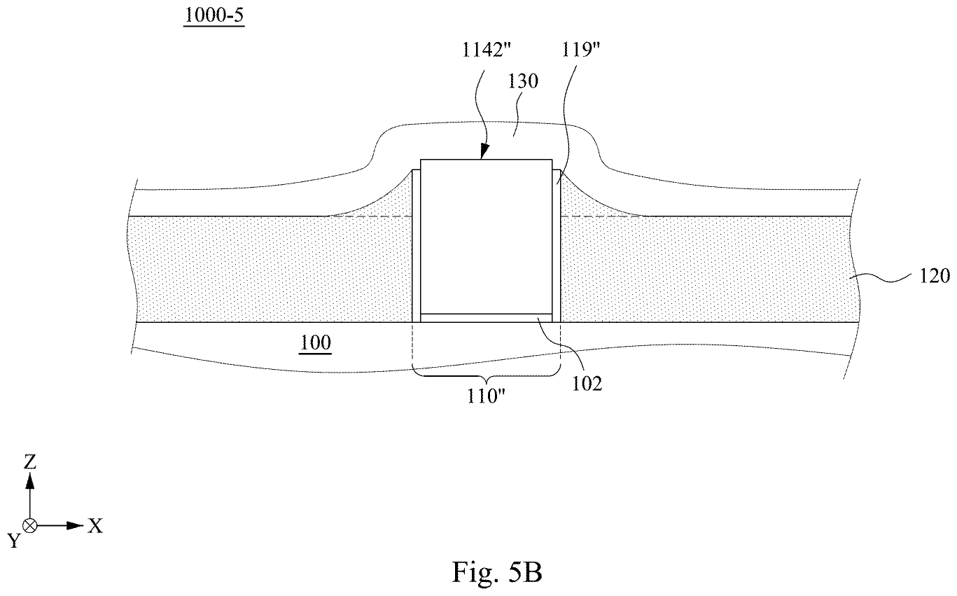

Reference is made to FIGS. 5A and 5B. FIG. 5A is a schematic cross-sectional view of a micro light-emitting diode device structure 1000-4 according to some embodiments of the present disclosure. FIG. 5B is a schematic cross-sectional view of a micro light-emitting diode device structure 1000-5 according to some embodiments of the present disclosure. In some embodiments, the micro light-emitting diodes 110′ or 110″ further includes a dielectric sidewall 119′ or 119″ surrounding and in contact with the first type semiconductor layer 112 and the second type semiconductor layer 114. In some embodiments, the dielectric sidewalls 119′ and 119″ are in contact with the isolation layer 120. Unlike the isolation layers 120 and 120′ that mask-free methods can make, the dielectric sidewalls 119′ and 119″ are much thinner than the isolation layers 120 and 120′ (e.g., the width in the X direction is smaller than 1 μm). The dielectric sidewalls 119′ and 119″ are mainly formed by a deposition method (e.g., atomic layer deposition or thermal evaporation). The dielectric sidewalls 119′ and 119″ can further protect the micro light-emitting diodes 110′ and 110″ and prevent short circuits within the micro light-emitting diodes 110′ and 110″. A difference between the micro light-emitting diode 110′ in FIG. 5A and the micro light-emitting diode 110″ in FIG. 5B is that: the dielectric sidewall 119′ covers and in contact with a part of a top surface 1142′ of the micro light-emitting diode 110′, while a top surface 1142″ of the micro light-emitting diode 110″ is completely exposed from the dielectric sidewall 119″.

In summary, the present disclosure provides a micro light-emitting diode device structure in which structural features of an isolation layer near a side surface of a micro light-emitting diode avoids cracks of a top electrode covering a top surface of the micro light-emitting diode. In addition, the structural features of the isolation layer prevent a short circuit between a p-type semiconductor layer and an n-type semiconductor layer of the micro light-emitting diode. The benefits are mainly achieved by the synergism of the following characteristics: (1) a lateral length of the micro light-emitting diode is smaller than 50 μm; (2) a ratio of the lateral length to a height of the micro light-emitting diode is smaller than 20; and (3) in a cross-section of the micro light-emitting diode device, an included angle as shown in the above embodiments is greater than 120 degrees.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A micro light-emitting diode device structure, comprising:
a substrate;
a micro light-emitting diode on the substrate, comprising:
a first type semiconductor layer;
a second type semiconductor layer on the first type semiconductor layer; and
an active layer between the first type semiconductor layer and the second type semiconductor layer, wherein a top surface of the second type semiconductor layer has a first height with respect to a front surface of the substrate, a ratio of a lateral length of the micro light-emitting diode to the first height is smaller than 20, and the lateral length is smaller than 50 μm;
an isolation layer on the substrate and surrounding the micro light-emitting diode, the isolation layer having a flat portion and a concave portion between the flat portion and the micro light-emitting diode, the flat portion having a flat surface facing away from the substrate, the concave portion having a concave surface facing away from the substrate, the concave portion being in contact with a side surface of the micro light-emitting diode, the second type semiconductor layer being exposed from the isolation layer; and
a top electrode covering and in contact with the second type semiconductor layer and the isolation layer, and wherein
a contact periphery between the micro light-emitting diode and the concave surface has a second height with respect to the front surface, the flat surface has a third height with respect to the front surface, the second height is greater than the third height and smaller than the first height, wherein a height of the isolation layer with respect to the front surface decreases from the second height to the third height in a direction away from the side surface; and
wherein in a cross-section of the micro light-emitting diode device structure perpendicular to the front surface, an included angle between the flat surface and a virtual straight line connecting the contact periphery and a turning periphery is greater than 120 degrees, the turning periphery is a boundary between the concave surface and the flat surface.

2. The micro light-emitting diode device structure of claim 1, wherein a difference between the first height and the second height is greater than 0 μm and smaller than 3.5 μm.

3. The micro light-emitting diode device structure of claim 1, wherein the first type semiconductor layer is a p-type semiconductor layer, and the second type semiconductor layer is an n-type semiconductor layer.

4. The micro light-emitting diode device structure of claim 3, wherein a thickness of the second type semiconductor layer is greater than a thickness of the first type semiconductor layer.

5. The micro light-emitting diode device structure of claim 1, wherein the substrate comprises a conductive layer thereon, the micro light-emitting diode further comprises a bonding electrode on the first type semiconductor layer, and the conductive layer is in contact with the bonding electrode.

6. The micro light-emitting diode device structure of claim 1, wherein in the cross-section, the concave surface is between an extension the flat surface and the virtual straight line.

7. The micro light-emitting diode device structure of claim 6, wherein in the cross-section, the virtual straight line, the side surface, and the extension of the flat surface form a triangular area, and a filling rate of an area of the isolation layer within the triangular area with respect to the triangular area is greater than 30%.

8. The micro light-emitting diode device structure of claim 1, wherein a refractive index of the isolation layer is smaller than a refractive index of the top electrode.

9. The micro light-emitting diode device structure of claim 8, wherein the refractive index of the top electrode is smaller than refractive indices of the first type semiconductor layer and the second type semiconductor layer.

10. The micro light-emitting diode device structure of claim 1, wherein the top electrode comprises metal nanowires.

11. The micro light-emitting diode device structure of claim 1, wherein a transmittance of the top electrode is greater than 60%.

12. The micro light-emitting diode device structure of claim 1, wherein a width of the isolation layer with respect to the side surface is greater than 1 μm.

13. The micro light-emitting diode device structure of claim 1, wherein side surfaces of the first type semiconductor layer and the active layer are entirely covered by and in contact with the isolation layer.

14. The micro light-emitting diode device structure of claim 1, wherein the first type semiconductor layer and the second type semiconductor layer are in contact with the isolation layer.

15. The micro light-emitting diode device structure of claim 1, wherein the micro light-emitting diode further comprises a dielectric sidewall surrounding and in contact with the first type semiconductor layer and the second type semiconductor layer.

16. The micro light-emitting diode device structure of claim 15, wherein the dielectric sidewall is in contact with the isolation layer.

17. The micro light-emitting diode device structure of claim 1, wherein a vertical projection of the contact periphery on the front surface is in the shape of a circle.

18. The micro light-emitting diode device structure of claim 1, wherein a vertical projection of the contact periphery on the front surface is in the shape of a polygon, and each of interior angles of the polygon is greater than 90 degrees.

19. A micro light-emitting diode device structure, comprising:
a substrate;
a micro light-emitting diode on the substrate, comprising:
a first type semiconductor layer;
a second type semiconductor layer on the first type semiconductor layer; and
an active layer between the first type semiconductor layer and the second type semiconductor layer, wherein a top surface of the second type semiconductor layer has a first height with respect to a front surface of the substrate, a ratio of a lateral length of the micro light-emitting diode to the first height is smaller than 20, and the lateral length is smaller than 50 μm;
an isolation layer on the substrate and surrounding the micro light-emitting diode, the isolation layer having a concave surface facing away from the substrate, the isolation layer being in contact with a side surface of the micro light-emitting diode, the second type semiconductor layer being exposed from the isolation layer; and
a top electrode covering and in contact with the second type semiconductor layer and the isolation layer, and wherein
a contact periphery between the micro light-emitting diode and the concave surface has a second height with respect to the front surface, the second height is smaller than the first height, wherein a height of the isolation layer with respect to the front surface decreases from the second height to zero in a direction away from the side surface; and
wherein in a cross-section of the micro light-emitting diode device structure perpendicular to the front surface, an included angle between the front surface and a virtual straight line connecting the contact periphery and a turning periphery is greater than 120 degrees, the turning periphery is a boundary between the concave surface and the front surface.
